(19) United States
(12) Patent Application Publication
(10) Pub. No.: US 2015/0129826 A1
(43) Pub. Date: May 14, 2015

(54) Flexible Non-Volatile Memory

(71) Applicant: Intermolecular Inc., San Jose, CA (US)

(72) Inventor: Yun Wang, San Jose, CA (US)

(73) Assignee: Intermolecular Inc., San Jose, CA (US)

(21) Appl. No.: 14/079,500

(22) Filed: Nov. 13, 2013

(51) Int. Cl. H01L 45/00

(52) U.S. Cl. CPC H01L 45/1226; H01L 45/1253; H01L 45/16
USPC 257/4; 438/382

(57) ABSTRACT

A flexible and/or transparent nonvolatile memory device can be fabricated on flexible substrates, together with ductile materials or transparent conductive oxide materials, and layers with thicknesses that allow flexibility and transparency. The ductile materials can include Ti, Ni, Nb, or Zr. The transparent conductive materials can include indium tin oxide, zinc oxide or aluminum doped zinc oxide. The nonvolatile memory devices can include resistive switching memory, phase change memory, magnetoresistive random access memory, or spin-transfer torque random access memory.

### FIELD OF THE INVENTION

This invention relates generally to non-volatile memory arrays, and more particularly, to methods for forming flexible and/or transparent non-volatile memory devices.

### BACKGROUND

Nonvolatile memory elements are used in systems in which persistent storage is required. For example, digital cameras use nonvolatile memory cards to store images and digital music players use nonvolatile memory to store audio data. Nonvolatile memory is also used to persistently store data in computer environments. Nonvolatile memory is often formed using electrically-erasable programmable read only memory (EPROM) technology. This type of nonvolatile memory contains floating gate transistors that can be selectively programmed or erased by application of suitable voltages to their terminals.

As fabrication techniques improve, it is becoming possible to fabricate nonvolatile memory elements with increasingly smaller dimensions. However, as device dimensions shrink, scaling issues are posing challenges for traditional nonvolatile memory technology. This has led to the investigation of alternative nonvolatile memory technologies, including resistive memory devices, such as resistive random access memory (ReRAM), phase change memory (PCM), magnetoresistive random access memory (MRAM), or spin-transfer torque random access memory (STTRAM).

Flexible electronics, also known as flex circuits, is a technology for assembling electronic circuits by mounting electronic devices on flexible plastic substrates, Flex circuits are often used as connectors in various applications where flexibility, space savings, or production constraints limit the serviceability of rigid circuit boards or hand wiring. However, typical resistive memory devices are fabricated on hard substrates such as silicon substrates.

Therefore, there is a need for flexible and/or transparent nonvolatile memory.

### SUMMARY

In some embodiments, the present invention discloses flexible and/or transparent nonvolatile memory devices, such as resistive switching memory, phase change memory, magnetoresistive random access memory, or spin-transfer torque random access memory.

In some embodiments, the flexible nonvolatile memory devices can be fabricated on flexible substrates, such as plastic. Further, conductive lines can be fabricated using ductile materials, such as Ti, Ni, Nb, or Zr. Other components, such as the switching layers of the resistive switching memory devices can be fabricated with thicknesses that allow flexibility in the memory devices, such as less than 10 nm, or less than 5 nm.

In some embodiments, the transparent nonvolatile memory devices can be fabricated on transparent substrates, such as glass or plastic. Further, conductive lines can be fabricated using transparent conductive materials, such as indium tin oxide (ITO) or ZnO. Other components, such as the switching layers of the resistive switching memory devices can be fabricated with thicknesses that allow transparency in the memory devices, such as less than 10 nm, or less than 5 nm.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a memory array of resistive switching memory elements according to some embodiments.

FIGS. 2A-2B illustrate an example of a memory stack according to some embodiments.

FIG. 3 illustrates a flexible substrate according to some embodiments.

FIG. 4 illustrates an optional process to prepare a flexible substrate according to some embodiments.

FIGS. 5A-5B illustrate cross section view and top view of a bottom electrode formation according to some embodiments.

FIGS. 6A-6B illustrate cross section view and top view of a switching layer formation according to some embodiments.

FIGS. 7A-7B illustrate cross section view and top view of a top electrode formation according to some embodiments.

FIG. 8 illustrates a capping process according to some embodiments.

FIG. 9 illustrates a memory stack including a current selector disposed on a memory structure according to some embodiments.

FIG. 10 illustrates a flowchart for forming a flexible memory device according to some embodiments.

FIG. 11 illustrates a flowchart for forming a flexible and transparent memory device according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

In some embodiments, flexible and/or transparent memory devices are provided that can be folded to fit into difficult spaces. In addition, the transparency characteristics can allow the incorporation of these memory devices into the device screen, such as information displayed on an automobile windshield, or surfing the web on the glass top of a coffee table.

In some embodiments, a cross-bar architecture is provided for flexible and/or transparent non-volatile memories, such as phase change memory (PCM), resistive random access memory (ReRAM), or spin-transfer torque random access memory (STTRAM), because of the small cell size of 4F² achievable with each cell at the intersections of perpendicular word lines and bit lines, and the potential to stack multiple layers to achieve very high memory density.

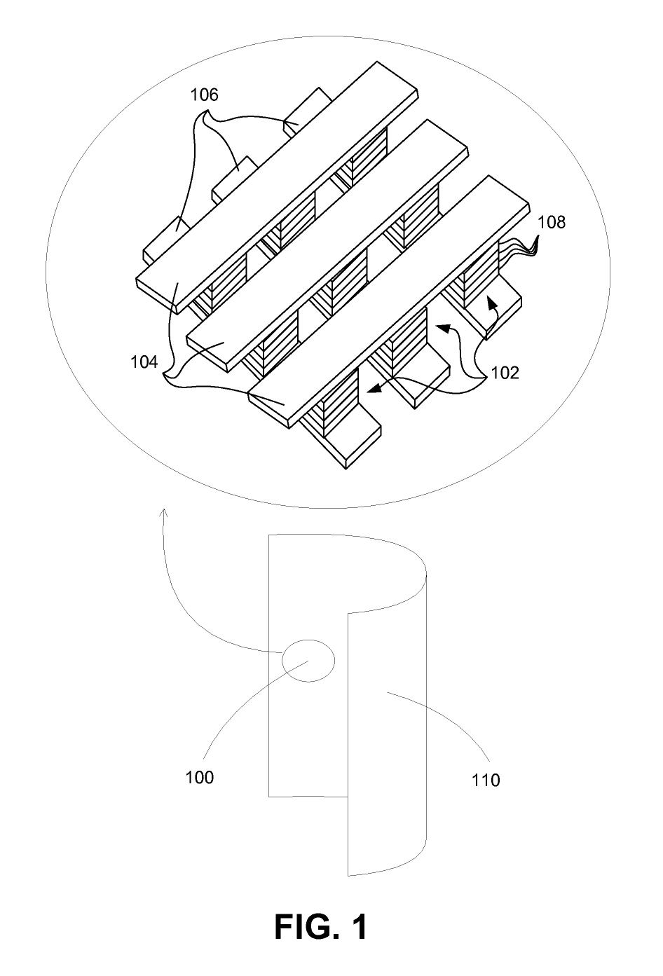

FIG. 1 illustrates a memory device of resistive switching memory elements according to some embodiments. Flexible panel 110 can include memory array 100, which may be part of a memory device or other integrated circuit. Memory array 100 is an example of potential memory configurations; it is understood that several other configurations are possible. In memory array 100, the memory cells can be configured in a cross point memory array. The cross point memory arrays can include horizontal word lines that cross vertical bit lines. Memory cells can be located at the cross points of the word lines and the bit lines.

Read and write circuitry may be connected to memory elements 102 using signal lines 104 and orthogonal signal lines 106. Signal lines such as signal lines 104 and signal lines 106 are sometimes referred to as word lines and bit lines and are used to read and write data into the elements 102 of array 100. Individual memory elements 102 or groups of memory elements 102 can be addressed using appropriate sets of signal lines 104 and 106. Memory element 102 may be formed from one or more layers 108 of materials, as is described in further detail below. In addition, the memory arrays shown can be stacked in a vertical fashion to make multi-layer 3-D memory arrays.

Any suitable read and write circuitry and array layout scheme may be used to construct a non-volatile memory device from resistive switching memory elements such as element 102. For example, horizontal and vertical lines 104 and 106 may be connected directly to the terminals of resistive switching memory elements 102. This is merely illustrative.

During the operation of the cross point memory array, such as a read operation, the state of a memory element 102 can be sensed by applying a sensing voltage (i.e., a “read” voltage) to an appropriate set of signal lines 104 and 106. Depending on its history, a memory element that is addressed in this way may be in either a high resistance state or a low resistance state. The resistance of the memory element therefore determines what digital data is being stored by the memory element. If the memory element has a low resistance, for example, the memory element may be said to contain a logic one (i.e., a “1” bit). If, on the other hand, the memory element has a high resistance, the memory element may be said to contain a logic zero (i.e., a “0” bit). During a write operation, the state of a memory element can be changed by application of suitable write signals to an appropriate set of signal lines 104 and 106.

Ideally, only the selected memory cell, e.g., during a read operation, can experience a current. However, currents, often referred as sneak path currents, can flow through unselected memory elements during the read operation. The sensing the resistance state of a single memory call can be unreliable. For example, all memory cells in the array are coupled together through many parallel paths. The resistance measured at one cross point can include the resistance of the memory cell at that cross point in parallel with resistances of the memory cells in the other rows and columns.

To reduce or eliminate the sneak path occurrence, a control device, e.g., a selector, can be used in the cross point memory array. For example, a diode can be located in each memory cell. The control device can isolate the selected memory cell from unselected memory cells by breaking parallel connections of the memory cells.

In some embodiments, methods and systems for a flexible and/or transparent panel incorporating nonvolatile memory devices is provided. For flexible panels, materials, layers, and processes can be selected to allow the bending of the fabricated devices, such as using ductile metals or alloys, thin layers, and processes compatible with flexible substrates. For transparent panels, materials, layers, and processes can be selected to allow the light transmission through the fabricated devices, such as using transparent conductive metal oxide, thin layers, and processes compatible with transparent substrates.

In some embodiments, memory devices, and methods to fabricate memory devices, for resistive memory elements and cross point memory array are provided. The flexible and/or transparent panels can be constructed using familiar and available materials currently used in fabrication facilities. The fabrication process of the flexible and/or transparent panels may require low thermal budget, suitable for back end or 3D memory applications. In addition, the process can be simple, providing a robust process for manufacturing.

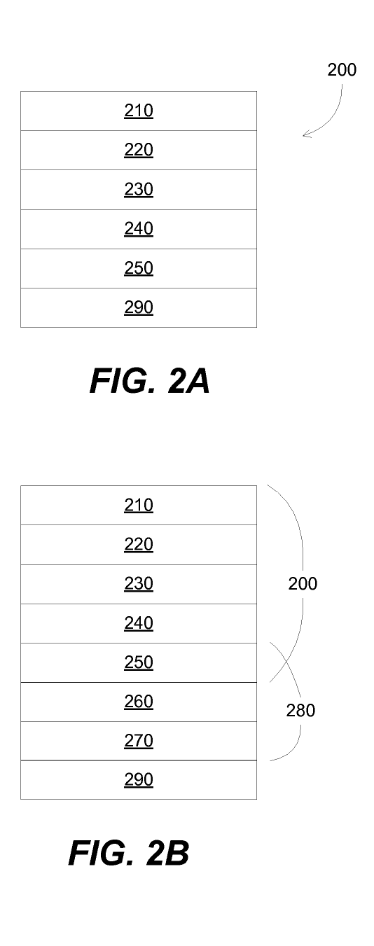

FIGS. 2A-2B illustrate an example of a memory stack according to some embodiments. A resistive switching memory element is shown, but the invention is not limited to the resistive switching memory devices, and can be equally applicable to other types of memory devices, such as PCM, MRAM, or STTRAM.

In FIG. 2A, a memory element 200 can be disposed on a substrate 290, and can include a first, e.g., bottom, electrode layer 270, a resistive switching layer 260, and a second, e.g., top, electrode layer 250. The two electrodes can be the same or can be different, e.g., different materials.

In FIG. 2B, the memory element 200 can be placed in series with a current selector 280, both of which are disposed on substrate 290. The current selector 280 can include a non-linear current response layer 240 sandwiched between two electrodes 230 and 250. As shown, the current selector 280 and the memory element 200 share a common electrode 250. The non-linear current response layer 240 can include a pn junction diode, which can allow current flow in one direction and blocking current flow in the opposite direction. In other cases, the current selector could be an embedded resistor.

In some embodiments, the memory device including a memory element and a current selector can be used in a memory array, such as a cross point array. For example, the current selector can be fabricated on the memory element, forming a columnar memory device, which can be placed at the cross points of the word lines and bit lines.

In some embodiments, provided are flexible nonvolatile memory devices, and methods to fabricate such flexible nonvolatile memory devices. The following description provides a detailed fabrication process for resistive switching memory devices in a cross point architecture. However, the invention is not so limited, and other structures can be used, such as could be vertical resistive random access memory (VRRAM). Other types of memory devices can be used, such as resistive switching memory, phase change memory, magnetoresistive random access memory, or spin-transfer torque random access memory.

In some embodiments, the components of the flexible nonvolatile memory devices can be selected to have flexible characteristics, such as thin polymer or plastic materials that are flexible, or metals or alloys that have high ductility characteristics. In general, the components of the flexible nonvolatile memory devices are chosen based on a trade-off between thickness and flexibility characteristics. For example, materials with high ductility or low hardness characteristics can have a medium thickness, such as between 1 and 100 microns. Materials with low ductility or high hardness characteristics can have a thin thickness, such as between 1 and 20 nanometers, such as less than 10 nm, or less than 5 nm. In some embodiments, in the context of the present invention, flexible devices or panels mean that the devices or panels can be bent, folded or twisted in certain degree. For example, the radius of curvature of a flexible panel can be less than 20 mm or less than 10 mm.

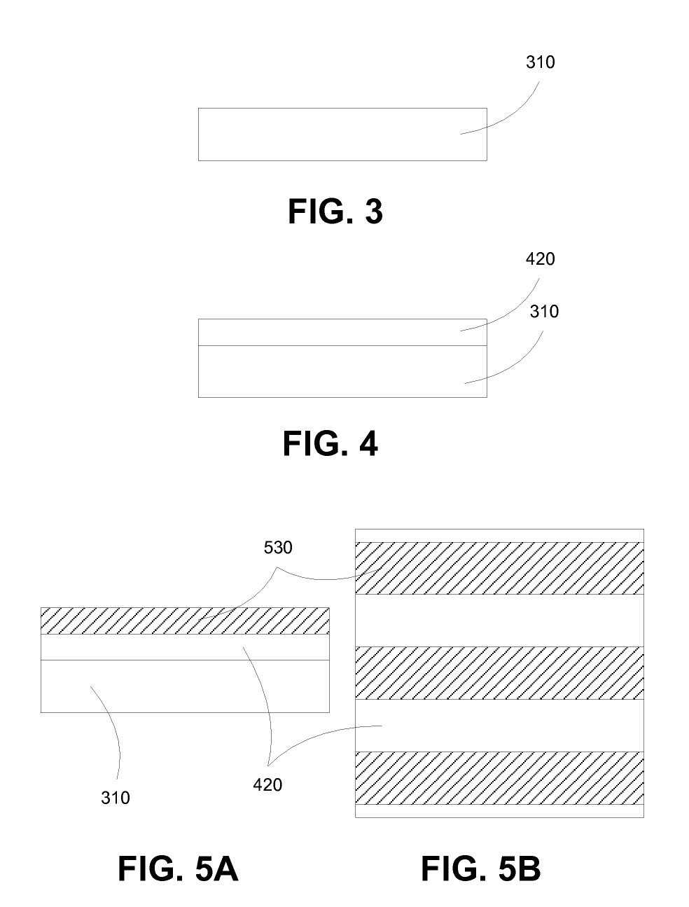

The following FIGS. 3-8 illustrate a process flow for forming a flexible memory device according to some embodiments.

FIG. 3 illustrates a flexible substrate according to some embodiments. The flexible substrate 310 can include a plastic substrate, such as polyether ether ketone (PEEK), polyether sulfone (PES), or polyimide. The flexible substrate can also include other thin substrates, such as metal or alloy substrates that are flexible. The flexible substrate can also be transparent, such as transparent conductive polyester. The flexible substrate can be bent, folded, or twisted. The flexible substrate can have a radius of curvature less than 20 mm or less than 10 mm. The thickness of the flexible substrate can be less than 500 microns, such as less than 200 microns or less than 100 microns.

In some embodiments, the flexible substrate can include polymer materials that can sustain high temperatures, such as less than 400 C. Further, the flexible substrate can be selected to withstand wet etch chemicals, such as chemicals used to etch metals (to pattern device electrodes) or metal oxides (to pattern the switching layer).

In some embodiments, the flexible substrate can be attached to a hard, e.g., non-flexible, substrate such as a silicon substrate or a glass substrate. The hard substrate can function as a carrier substrate, allowing ease of substrate processing. The carrier substrates can be used in some semiconductor equipment that requires hard substrates or in some semiconductor equipment where flexible substrates might create some difficulty in processing. The flexible substrate can be temporarily bonded to the carrier substrate, such as gluing, which can allow the separation of the flexible substrates when the processing is complete.

FIG. 4 illustrates an optional process to prepare a flexible substrate according to some embodiments. A passivation layer 420 can be formed on the flexible substrate 310. The passivation layer can reduce the roughness of the flexible substrate. The passivation layer can include a flexible layer, such as a thin silicon dioxide layer of less than 200 nm, such as about 100 nm. In some embodiments, the flexible substrate can be cleaned before continuing processing, such as cleaning before depositing the passivation layer, or cleaning before the next step, in the case the passivation layer is omitted. The cleaning process can function to remove surface defects and debris, such as organic films or particulates on the flexible substrate surface. A wet surface clean can be used, such as an HF clean for removing oxides, a standard clean 1 (SC1), using a solution of NH₄OH and H₂O₂ for removing organic contaminants, or standard clean 2 (SC2), using a solution of HCl and H₂O₂ for removing metallic or ionic contaminants.

FIGS. 5A-5B illustrate cross section view and top view of a bottom electrode formation according to some embodiments. A bottom electrode layer 530 can be formed on the flexible substrate 310, for example, on the optional passivation layer 420. The bottom electrode layer 530 can be blanketly deposited, and then patterned to form conductive lines in a first direction, such as a horizontal direction as shown in the figures. The bottom electrode layer 530 can be deposited by a physical vapor deposition (PVD) process, or by other vacuum based deposition processes such as evaporation, chemical vapor deposition (CVD), or atomic layer deposition (ALD). The patterning process can be performed by a wet etch process.

In some embodiments, the bottom electrode layer is configured to be flexible. For example, the materials for the bottom electrode layer can include metal materials that are highly ductile, such as Ti, Nb, Au, Zr, Ni, V, or any combination thereof. In general, there is a trade-off between ductility and strength characteristics. For example, Ti, Zr, Ni, and Nb can be used for the flexible electrode. In addition, these materials have been demonstrated as suitable electrodes for resistive switching memory stacks. The resistivity of the bottom electrode layer can be low, e.g., less than about 1 mΩ-cm, to reduce the load resistance and voltage drop.

In some embodiments, the thickness of the bottom electrode layer 530 can have any thickness (as long as it is flexible), such as less than about 500 nm, or between 5 nm and 500 nm.

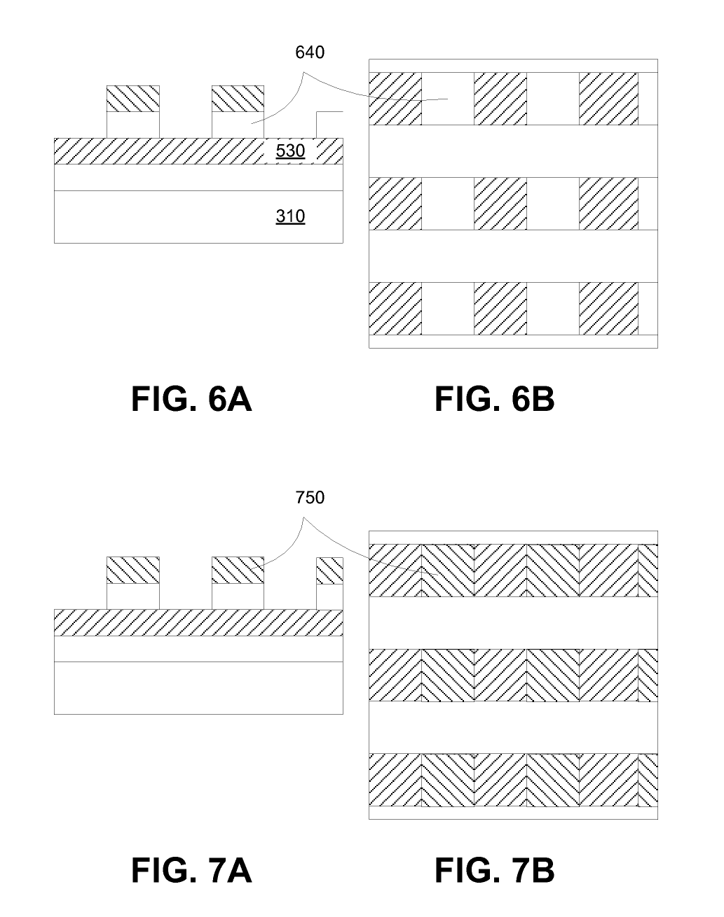

FIGS. 6A-6B illustrate cross section view and top view of a switching layer formation according to some embodiments. The switching layer can include a transition metal oxide, such as an oxide of a transition metal of Hf, Ta, Ti, or Al. The switching layer can be a single layer or a multi-layer. A switching layer 640 can be formed on the flexible substrate 310, for example, on the bottom electrode layer 530. The switching layer 640 can be blanketly deposited, and then patterned to form switching elements on the bottom electrode conductive lines. The switching layer 640 can be deposited by a physical vapor deposition (PVD) process, or by other vacuum based deposition processes such as evaporation, chemical vapor deposition (CVD), or atomic layer deposition (ALD). The patterning process can be performed by a lithography and wet or dry etch process.

In some embodiments, the switching layer can include a metal oxide material. For example, transition metal oxide and its nitride or its ternary compounds can be good switching layer. Typical metal oxide can be HfOₓ, TaOₓ, TiOₓ, AlOₓ, ZrOₓ, SiOₓ, or corresponding MeSiOₓ, MeN, MeSiN, MeSiON, with Me being the metal components in the metal oxides listed above, e.g., HfSiOₓ, HfSiON, SiON, SiN, TaSiOₓ, TiSiOₓ, AlSiOₓ, ZrSiOₓ, HfN, TaN, TiN, AlN, ZrN, HfSiN, TaSiN, TiSiN, AlSiN, or ZrSiN.

In some embodiments, the switching layer is configured to be flexible. For example, the thickness of the switching layer can be less than about 10 nm, less than about 5 nm, or less than about 3 nm.

FIGS. 7A-7B illustrate cross section view and top view of a top electrode formation according to some embodiments. A top electrode layer 750 can be formed on the flexible substrate 310, for example, on the optional switching layer 530. The top electrode layer 530 can be blanketly deposited, and then patterned to form conductive lines in a second direction, forming an angle with the first direction, such as a vertical direction as shown in the figures. The top electrode layer 530 can be deposited by a physical vapor deposition (PVD) process, or by other vacuum based deposition processes such as evaporation, chemical vapor deposition (CVD), or atomic layer deposition (ALD). The patterning process can be performed by a wet etch process.

In some embodiments, the top electrode layer is configured to be flexible. For example, the materials for the top electrode layer can be similar to those of the bottom electrode layer, such as metal materials that are highly ductile, such as Ti, Nb, Au, Zr, Ni, V, or any combination thereof. For example, Ti, Zr, Ni, and Nb can be used for the flexible electrode. In addition, these materials have been demonstrated as suitable electrodes for resistive switching memory stacks. The resistivity of the top electrode layer can be low, e.g., less than about 1 mΩ-cm, to reduce the load resistance and voltage drop.

In some embodiments, the thickness of the top electrode layer 750 can have any thickness (as long as it is flexible), such as less than about 500 nm, or between 5 nm and 500 nm.

The formation of the bottom electrode, the switching layer, and the top electrode can be repeated multiple times, for example, for 3D stacking to increase the memory density.

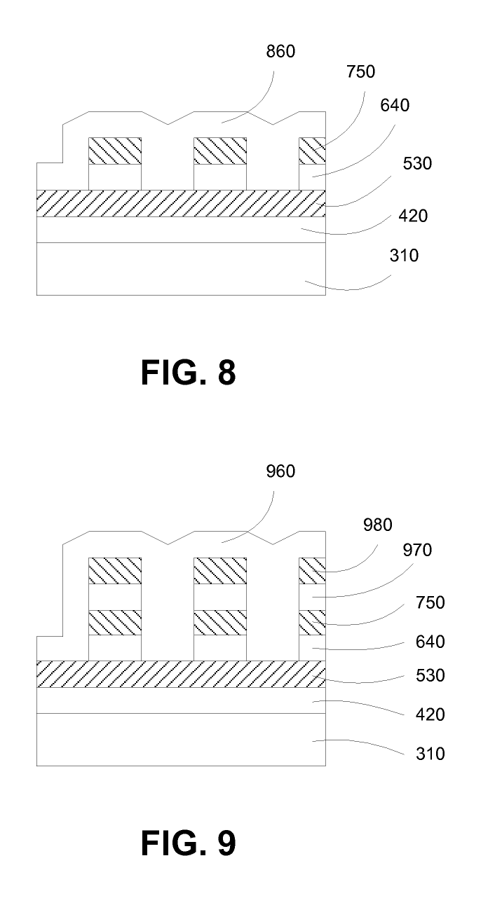

FIG. 8 illustrates a capping process according to some embodiments. A cap layer 860 can be blanketly deposited on the memory structures, e.g., a structure including the bottom electrode 530, the switching layer 640, and the top electrode 750. The cap layer can be configured to be flexible. The cap layer materials can include materials similar to those of the flexible substrate 310.

Other device configurations can be used. For example, a current selector device can be fabricated on the memory structure. The current selector can include a pn structure or a metal-insulator-metal (MIM) structure.

FIG. 9 illustrates a memory stack including a current selector disposed on a memory structure according to some embodiments. After forming the memory structure (top electrode 750 on switching layer 640 on bottom electrode 530), a current selector structure (including electrode layer 980 on a current selector layer 970 on electrode layer 750) is formed. As shown, the memory structure and the current selector structure share a common electrode 750. A cap layer 960 can be formed on the memory stack.

In some embodiments, the materials of the current selector layer can be similar to those of the electrodes, e.g., including Ti, Zr, Ni, Nb, or any combination thereof. However, while the electrodes are configured to have low resistivity, e.g., less than 1 mΩ-cm, the resistivity of the current selector layer is configured to be greater than 100 mΩ-cm, such as between 0.1 and 10 Ω-cm. In other words, the resistance of the current selector layer can be between 1 and 100 kΩ for 10-100 nm line width devices.

Other memory structures can also be formed. For example, the top electrode 750 can be optional, e.g., the current selector layer 970 can be fabricated directly on the switching layer 640, forming a memory stack including a bottom electrode layer 420, a switching layer 530, a current selector layer 970, and an electrode layer 980.

Further, multiple layers of memory stacks can be fabricated on top of each other to form a 3D array cross bar resistivity switching memory. Further, other non-volatile memory can also be used (e.g. PCM, MRAM, and STTRAM).

In some embodiments, transparent nonvolatile memory devices, and methods to fabricate the transparent nonvolatile memory devices, are provided. For transparent devices, the conductive lines can be fabricated using transparent conductive materials, such as indium tin oxide (ITO), ZnO, or aluminum doped zinc oxide (AZO). Other components, such as the switching layers of the resistive switching memory devices can be fabricated with thicknesses that allow transparency in the memory devices, such as less than 10 nm, or less than 5 nm.

In some embodiments, the nonvolatile memory devices can be both flexible and transparent. The flexible and transparency can be achieved by replacing the metal electrode with transparent conductive oxide (e.g. ITO, ZnO or AZO). Further, the oxide thickness can be as thin as possible, for example, to achieve the good optical transmittance. Metal oxide having thickness of 3 nm has been demonstrated as the switching layer. In some embodiments, switching layer having metal oxide can be as thin as 3 nm, e.g., between 3 and 5 nm, which can exhibit good transparency for the memory stack.

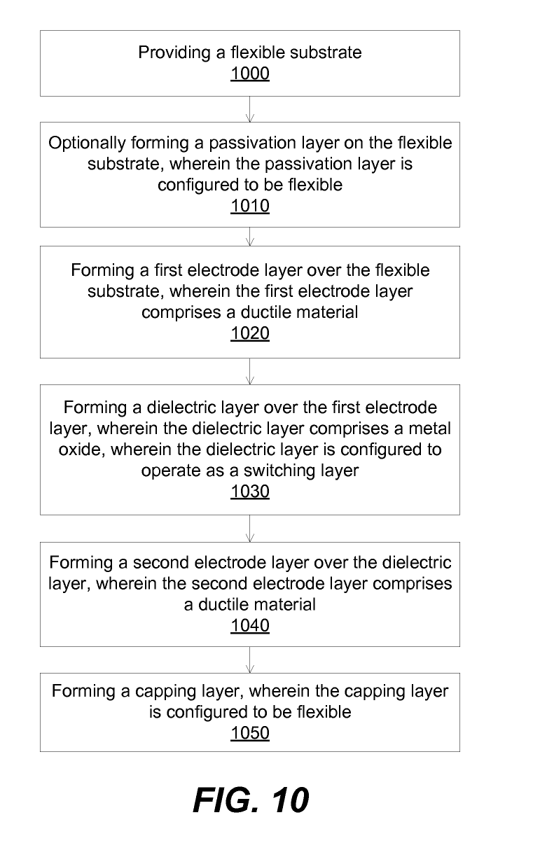

FIG. 10 illustrates a flowchart for forming a flexible memory device according to some embodiments. The described flowchart is a general description of techniques used to form the flexible memory devices described above. The flowchart describes techniques for forming a flexible memory device generally including two electrodes and multiple layers disposed therebetween. Although certain processing techniques and specifications are described, it is understood that various other techniques and modifications of the techniques described herein may also be used.

In operation 1000, a flexible substrate is provided. The flexible substrate can include any substrate that is flexible, meaning the flexible substrate can be bent, folded, or twisted with a radius of curvature less than 20 mm or less than 10 mm. The flexible substrate can include a plastic substrate, or a thin metal substrate. In some embodiments, the flexible substrate can be attached to a non-flexible substrate for ease of processing. In some embodiments, the flexible substrate can include other layers or devices, for example, support devices for the memory devices.

In some embodiments, the flexible substrate can be cleaned before continuing processing. A wet surface clean can be used, such as an HF clean, a standard clean 1 (SC1), or q standard clean 2 (SC2).

In operation 1010, an optional passivation layer can be formed on the flexible substrate. The passivation layer is configured to be flexible, for example, by being sufficiently thin. The passivation layer can be operated to reduce the roughness of the flexible substrate, or to change a characteristic of the flexible substrate, such as the resistance of the flexible substrate.

In operation 1020, a first electrode layer can be formed over the flexible substrate or over the passivation layer. The first electrode layer includes a conductive ductile material, such as a ductile metal or alloy. The first electrode layer can be blanketly deposited, and then wet etched to form conductive lines. The bottom electrode layer can be deposited by physical vapor deposition (PVD), chemical vapor deposition (CVD), or atomic layer deposition (ALD).

In operation 1030, a dielectric layer is formed over the first electrode layer. The dielectric layer can include a metal oxide, which is operated as a switching layer for a resistive switching memory device. The dielectric layer can include other materials for other types of memory devices.

The dielectric layer can be blanketly deposited, and then patterned, e.g., wet etched, to form the switching layer. Since the first electrode layer is patterned, e.g., including multiple conductive lines, a blanket layer can be deposited on both the first electrode layer (e.g., on the conductive lines forming the first electrode layer) and on the substrate, e.g., the passivation layer if there is a passivation layer. A patterning process can be performed, for example, by a photolithography process, including a wet etch or a dry etch process to remove a portion of the blanket layer. The dielectric layer then includes multiple switching elements disposed on the first electrode conductive lines.

In some embodiments, the switching layer is configured to be flexible. For example, the thickness of the switching layer can be less than about 10 nm, less than about 5 nm, or less than about 3 nm.

An optional treatment can be performed after depositing the dielectric layer. The treatment can include a plasma treatment or a high temperature treatment. For example, the treatment can include a rapid thermal oxidation at temperature below 400 C in oxygen ambient. The treatment can be performed in-situ after the deposition of the first electrode layer. The treatment can include an oxygen radical anneal, e.g., plasma anneal in an oxygen ambient.

In operation 1040, a second electrode layer is formed over the dielectric layer. The second electrode layer includes a ductile material.

The second electrode layer can be blanketly deposited, and then patterned to form conductive lines in a direction that forms an angle with the direction of the multiple lines of the first electrode layer. The dielectric layer can be placed at the cross points of the multiple lines of the first and second electrode layers. The second electrode layer is also configured to be flexible.

The formation of the first electrode, the switching layer, and the second electrode can be repeated multiple times, for example, for 3D stacking to increase the memory density.

In some embodiments, a current selector device can be formed on the second electrode layer. In some embodiments, the second electrode layer can be omitted, e.g., a current selector device can be formed directly on the switching layer.

A current selector layer and a current selector electrode can be formed on the memory element (including the first electrode, the switching layer, and the second electrode). The current selector can include a conductive material, such as the materials of the electrode layers, but with a higher resistivity. The current selector layer and the current selector electrode are also configured to be flexible. In operation 1050, a capping layer is formed. The capping layer is configured to be flexible

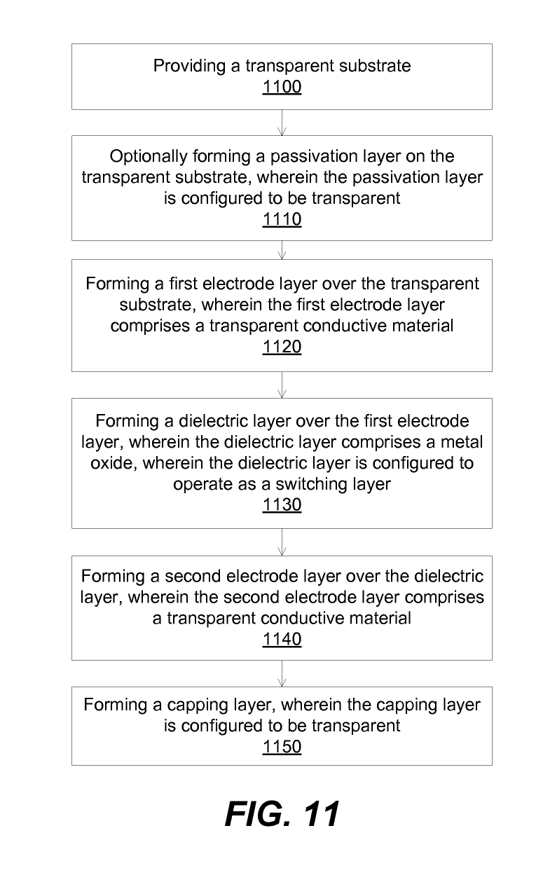

FIG. 11 illustrates a flowchart for forming a flexible and transparent memory device according to some embodiments. In operation 1100, a flexible and transparent substrate is provided. The flexible and transparent substrate can include any flexible substrate that is transparent. The flexible and transparent substrate can include a plastic substrate.

In some embodiments, the substrate can be cleaned before continuing processing. A wet surface clean can be used, such as an HF clean, a standard clean 1 (SC1), or q standard clean 2 (SC2).

In operation 1110, an optional passivation layer can be formed on the substrate. The passivation layer is configured to be transparent and flexible, for example, by being sufficiently thin. The passivation layer can be operated to reduce the roughness of the substrate, or to change a characteristic of the substrate, such as the resistance of the substrate.

In operation 1120, a first electrode layer can be formed over the substrate or over the passivation layer. The first electrode layer includes a transparent conductive oxide material, such as indium tin oxide (ITO), ZnO, or aluminum doped zinc oxide (AZO). The first electrode layer can be blanketly deposited, and then wet or dry etched to form conductive lines. The bottom electrode layer can be deposited by physical vapor deposition (PVD), chemical vapor deposition (CVD), or atomic layer deposition (ALD).

In operation 1130, a dielectric layer is formed over the first electrode layer. The dielectric layer can include a metal oxide, which is operated as a switching layer for a resistive switching memory device. The dielectric layer can include other materials for other types of memory devices.

In some embodiments, the switching layer is configured to be flexible and transparent. For example, the thickness of the switching layer can be less than less than about 5 nm, or less than about 3 nm. An optional treatment can be performed after depositing the dielectric layer.

In operation 1140, a second electrode layer is formed over the dielectric layer. The second electrode layer can include similar materials as those of the first electrode layer, such as transparent conductive oxide materials of indium tin oxide (ITO), ZnO, or aluminum doped zinc oxide (AZO).

The formation of the first electrode, the switching layer, and the second electrode can be repeated multiple times, for example, for 3D stacking to increase the memory density.

In some embodiments, a current selector device can be formed on the second electrode layer. In some embodiments, the second electrode layer can be omitted, e.g., a current selector device can be formed directly on the switching layer.

A current selector layer and a current selector electrode can be formed on the memory element (including the first electrode, the switching layer, and the second electrode). The current selector can include a transparent conductive material, such as the materials of the electrode layers, but with a higher resistivity. The current selector layer and the current selector electrode are also configured to be flexible and transparent. In operation 1150, a capping layer is formed. The capping layer is configured to be flexible and transparent, for example, by being sufficiently thin.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A method to form a flexible non-volatile memory, the method comprising
providing a flexible substrate;
forming a first electrode layer over the flexible substrate,
wherein the first electrode layer comprises Ti, Ni, Zr, Nb, or any combination thereof,
wherein the first electrode layer comprises multiple lines running in a first direction;
forming a dielectric layer over the first electrode layer,
wherein the dielectric layer comprises a metal oxide material,
wherein the dielectric layer is less than 10 nm thick,
wherein the dielectric layer is configured to operate as a switching layer;
forming a second electrode layer over the flexible substrate,
wherein the second electrode layer comprises Ti, Ni, Zr, Nb, or any combination thereof,
wherein the second electrode layer comprises multiple lines running in a second direction, wherein the second direction forms an angle with the first direction,
wherein the dielectric layer comprises multiple portions disposed at cross points of the first and second electrode layers.

2. A method as in claim 1 wherein the flexible substrate comprises a polyether ether ketone (PEEK), polyether sulfone (PES), or polyimide substrate.

3. A method as in claim 1 further comprising
cleaning the flexible substrate using HF, a solution of NH₄OH and H₂O₂, or a solution of HCl and H₂O₂.

4. A method as in claim 1 further comprising
forming a passivation layer over the flexible substrate.

5. A method as in claim 1 further comprising
forming a silicon oxide layer over the flexible substrate.

6. A method as in claim 1 wherein the dielectric layer comprises at least one of HfOₓ, TaOₓ, TiOₓ, AlOₓ, ZrOₓ, SiOₓ, HfSiOₓ, HfSiON, SiON, SiN, TaSiOₓ, TiSiOₓ, AlSiOₓ, ZrSiOₓ, HfN, TaN, TiN, AlN, ZrN, HfSiN, TaSiN, TiSiN, AlSiN, or ZrSiN.

7. A method as in claim 1 wherein the dielectric layer is less than 5 nm thick.

8. A method as in claim 1 wherein the dielectric layer is 3 nm thick.

9. A method as in claim 1 further comprising
forming a cap layer over the flexible substrate,
wherein the cap layer comprises a flexible dielectric material.

10. A method to form a flexible and transparent non-volatile memory, the method comprising
providing a substrate, wherein the substrate is flexible and transparent;
forming a first electrode layer over the substrate,
wherein the first electrode layer comprises a transparent conductive metal oxide,
wherein the first electrode layer is operable to be flexible,
wherein the first electrode layer comprises multiple lines running in a first direction;
forming a dielectric layer over the first electrode layer,
wherein the dielectric layer comprises a metal oxide material,
wherein the dielectric layer is less than 5 nm thick,
wherein the dielectric layer is configured to operate as a switching layer;
forming a second electrode layer over the substrate,
wherein the first electrode layer comprises a conductive metal oxide,
wherein the first electrode layer is operable to be flexible,
wherein the second electrode layer comprises multiple lines running in a second direction, wherein the second direction forms an angle with the first direction,
wherein the dielectric layer comprises multiple portions disposed at cross points of the first and second electrode layers;
forming a cap layer over the substrate,
wherein the cap layer is operable to be flexible and transparent.

11. A method as in claim 10 wherein the substrate comprises a transparent conductive polyester substrate.

12. A method as in claim 10 further comprising
cleaning the substrate using HF, a solution of NH₄OH and H₂O₂, or a solution of HCl and H₂O₂.

13. A method as in claim 10 wherein the dielectric layer comprises at least one of HfOₓ, TaOₓ, TiOₓ, AlOₓ, ZrOₓ, SiOₓ, HfSiOₓ, HfSiON, SiON, SiN, TaSiOₓ, TiSiOₓ, AlSiOₓ, ZrSiOₓ, HfN, TaN, TiN, AlN, ZrN, HfSiN, TaSiN, TiSiN, AlSiN, or ZrSiN.

14. A method as in claim 10 wherein the dielectric layer is 3 nm thick.

15. A method as in claim 10 further comprising
forming a cap layer over the substrate,
wherein the cap layer comprises a flexible dielectric material,
wherein the cap layer comprises a material similar to that of the substrate.

16. A flexible and transparent memory array comprising
a substrate, wherein the substrate is flexible and transparent;
a first plurality of conductive lines,
wherein the first plurality of conductive lines comprises a transparent conductive metal oxide,
wherein the first plurality of conductive lines is operable to be flexible;
a second plurality of conductive lines,
wherein the second plurality of conductive lines is formed an angle with the first plurality of conductive lines,
wherein the second electrode layer comprises a transparent conductive metal oxide,
wherein the second electrode layer is operable to be flexible,
a plurality of elements disposed at the cross points of the first and second plurality of conductive lines,
wherein each element comprises a metal oxide material,
wherein the dielectric layer is less than 5 nm thick,
wherein the dielectric layer is configured to operate as a switching layer.

17. A flexible and transparent memory array as in claim 16 wherein the substrate comprises a transparent conductive polyester substrate.

18. A flexible and transparent memory array as in claim 16 wherein the dielectric layer comprises at least one of HfOₓ, TaOₓ, TiOₓ, AlOₓ, ZrOₓ, SiOₓ, HfSiOₓ, HfSiON, SiON, SiN, TaSiOₓ, TiSiOₓ, AlSiOₓ, ZrSiOₓ, HfN, TaN, TiN, AlN, ZrN, HfSiN, TaSiN, TiSiN, AlSiN, or ZrSiN.

19. A flexible and transparent memory array as in claim 16 wherein the dielectric layer is 3 nm thick.

20. A flexible and transparent memory array as in claim 16 further comprising
a cap layer over the substrate,
wherein the cap layer comprises a flexible dielectric material,
wherein the cap layer comprises a material similar to that of the substrate.
